(19) United States
(12) Patent Application Publication
(10) Pub. No.: US 2011/0088763 A1
(43) Pub. Date: Apr. 21, 2011

(54) METHOD AND APPARATUS FOR IMPROVING PHOTOVOLTAIC EFFICIENCY

(75) Inventors: Hien-Minh Huu Le, San Jose, CA (US); Mohd Fadzli Anwar Hassan, Sunnyvale, CA (US); David Tanner, San Jose, CA (US); Dapeng Wang, Santa Clara, CA (US)

(73) Assignee: APPLIED MATERIALS, INC., Santa Clara, CA (US)

(21) Appl. No.: 12/904,902

(22) Filed: Oct. 14, 2010

Related U.S. Application Data
(60) Provisional application No. 61/252,023, filed on Oct. 15, 2009.
(60) Provisional application No. 61/301,036, filed on Feb. 3, 2010.

(51) Int. Cl. H01L 31/0232; H01L 31/032; C23C 14/34

(52) U.S. Cl. 136/255; 438/95; 204/192.29; 257/E31.029

(57) ABSTRACT

A method and apparatus for improving efficiency of photovoltaic cells by improving light capture between the photoelectric unit and back reflector is provided. A transition layer is formed at the interface between the photoelectric unit and transmitting conducting layer of the back reflector by adding oxygen, nitrogen, or both to the surface of the photoelectric unit or the interface between the photoelectric unit and the transmitting conducting layer. The transition layer may comprise silicon, oxygen, or nitrogen, and may be silicon oxide, silicon nitride, metal oxide with excess oxygen, metal oxide with nitrogen, or any combination thereof, including bilayers and multi-layers. The sputtering process for forming the transmitting conducting layer may feature at least one of nitrogen and excess oxygen, and may be performed by sputtering at low power, followed by an operation to form the rest of the transmitting conductive layer.

### CROSS-REFERENCE TO RELATED APPLICATIONS

This application claims benefit of both U.S. provisional patent application Ser. No. 61/252,023, filed Oct. 15, 2009 and U.S. provisional patent application Ser. No. 61/301,036, filed Feb. 3, 2010. Each of the aforementioned related patent applications is herein incorporated by reference.

### FIELD

The present invention relates to methods and apparatus for depositing a transparent conductive film, more specifically, for reactively sputter depositing a transparent conductive film with high transmittance suitable for photovoltaic devices.

### BACKGROUND

Photovoltaic (PV) devices or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power.

Several types of silicon films, including microcrystalline silicon films (μc-Si), amorphous silicon films (a-Si), polycrystalline silicon films (poly-Si) and the like, may be utilized to form PV devices. A transparent conductive film may be used as a top surface electrode, often referred to as a back reflector, disposed on the top of the PV solar cells. Furthermore, the transparent conductive film may be disposed between a substrate and a photoelectric conversion unit as a contact layer. The transparent conductive film must have high optical transmittance in the visible or higher wavelength region to facilitate transmitting sunlight into the solar cells without adversely absorbing or reflecting light energy. Additionally, low contact resistance and high electrical conductivity of the transparent conductive film are desired to provide high photoelectric conversion efficiency and electricity collection. Certain degrees of texture or surface roughness of the transparent conductive layer are also desired to assist sunlight trapping in the films by promoting light scattering. Overly high impurities or contaminants of the transparent conductive film often result in high contact resistance at the interface of the transparent conductive film and adjacent films, thereby reducing carrier mobility within the PV cells. Furthermore, insufficient transparency of the transparent conductive film may adversely reflect light back to the environment or absorb light, resulting in a diminished amount of sunlight converted to electricity and a reduction in the photoelectric conversion efficiency.

Therefore, there is a need for an improved method for depositing a transparent conductive film for PV cells.

### SUMMARY OF THE INVENTION

Embodiments described herein provide a method of forming a solar cell by forming a photoelectric unit on a substrate, forming a transparent conductive layer on the substrate, and forming a high transmissivity interface layer between the photoelectric conversion layer and the transparent conductive layer.

Other embodiments provide a method of forming a transparent conductive layer by supplying a gas mixture to a processing chamber, sputtering a source material from a target comprising zinc and aluminum in the processing chamber, adding excess oxygen to the gas mixture, and reacting the source material with the gas mixture to deposit a transparent conductive layer that has excess oxygen.

Other embodiments provide a solar cell device with a photoelectric unit, a transmissive conductive layer adjacent to the photoelectric junction, and a high transmissivity interface layer between the photoelectric junction and the transmissive conductive layer.

### BRIEF DESCRIPTION OF THE DRAWINGS

So that the manner in which the above-recited features of the present inventions can be understood in detail, a more particular description may be had by reference to embodiments, some of which are illustrated in the appended drawings. It is to be noted, however, that the appended drawings illustrate only typical embodiments and are therefore not to be considered limiting of scope, for the inventions represented by these embodiments may admit to other equally effective embodiments.

FIG. 1 depicts a schematic cross-sectional view of a process chamber used in accordance with one embodiment.

FIG. 2 depicts an exemplary cross sectional view of a crystalline silicon-based thin film PV solar cell in accordance with another embodiment.

FIG. 3 depicts a process flow diagram of manufacturing a TCO layer in accordance with another embodiment.

FIG. 4 depicts an exemplary cross sectional view of a tandem type PV solar cell in accordance with another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein provide methods for forming a transition layer between a semiconductor photoelectric conversion layer and a back contact layer of a solar cell. The transition layer generally reduces recombination of carriers at the interface and/or reflects light back into the photoelectric conversion layer to improve overall efficiency. The back contact layer is generally formed by sputter depositing a transparent conductive layer, such as a transparent conductive oxide layer (TCO layer) on the photovoltaic substrate. The transition layer is formed between the photoelectric conversion layer and the TCO layer, and is preferably a high transmittance layer to avoid introducing absorption. In one embodiment, the TCO layer is sputter deposited by supplying different process gas mixtures along with different target material selections to deposit a TCO layer having a desired dopant concentration formed therein. Composition of the TCO layer at its interface with another layer, or surface of a substrate, can influence the reflection of light from the interface and recombination of carriers at the interface, each of which affects the efficiency of the solar cell. Embodiments of transition layers may be used to manage these impacts.

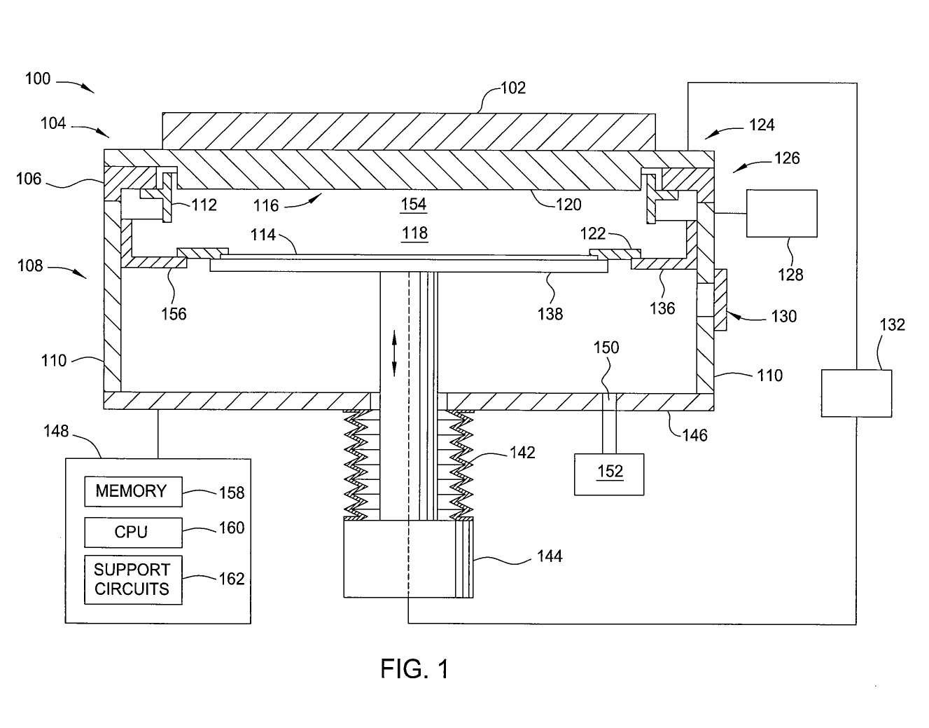

FIG. 1 schematically illustrates a PVD chamber 100 suitable for sputter depositing materials according to one embodiment. While the discussion and related figures shown herein illustrate a planar magnetron type process chamber 100, this configuration is not intended to be limiting as to the scope of the invention described herein, since cylindrical and other shaped targets may also be used. One example of a non-planar type PVD processing chamber that may be adapted to benefit from the invention is an ATON™ 5.7 PVD system, available from the Applied Films division of Applied Materials, Inc., located in Santa Clara, Calif. It is contemplated that other PVD chambers may be used as well, including chambers from other manufacturers.

The process chamber 100 includes a chamber body 108 having a processing volume 118 defined therein. The chamber body 108 has sidewalls 110 and a bottom 146. A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 114 (i.e., a solar panel, a flat panel display substrate, a semiconductor wafer, or other workpiece) into and out of the process chamber 100. A gas source 128 is coupled to the chamber body 108 to supply process gases into the processing volume 118. A pumping port 150 is formed through the bottom 146 of the chamber body 108. A pumping device 152 is coupled to the processing volume 118 to evacuate and control the pressure therein. The lid assembly 104 generally includes a target 120 and a ground shield assembly 126 coupled thereto. A high voltage power supply, such as a power source 132, is connected to the target 120 to facilitate the sputtering of material from the target 120. Optionally, the lid assembly 104 may further comprise a magnetron assembly 102 mounted above the target 120 which enhances efficient sputtering materials from the target 120 during processing. Examples of the magnetron assembly 102 include a linear magnetron, a serpentine magnetron, a spiral magnetron, a double-digitated magnetron, a rectangularized spiral magnetron, among others. A controller 148, including a central processing unit (CPU) 160, a memory 158, and support circuits 162, is coupled to the process chamber 100.

The ground shield assembly 126 of the lid assembly 104 includes a ground frame 106 and a ground shield 112. The ground shield assembly 126 may also include a chamber shield, a target shield, a dark space shield, and/or a dark space shield frame. The ground shield 112 is coupled to a peripheral portion 124 of the target 120 by the ground frame 106 defining an upper processing region 154 below the central portion of the target 120 in the processing volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source to be mainly deposited on the substrate surface rather than chamber sidewalls 110.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing by an actuator 144, an outer edge of the substrate 114 disposed on the substrate support 138 is engaged by the shadow frame 122 and the shadow frame 122 is lifted up and spaced away from the chamber shield 136. When the substrate support 138 is lowered to the transfer position adjacent to the substrate access port 130, the shadow frame 122 is set back on the chamber shield 136. A bellows 142 maintains a seal around the substrate support shaft.

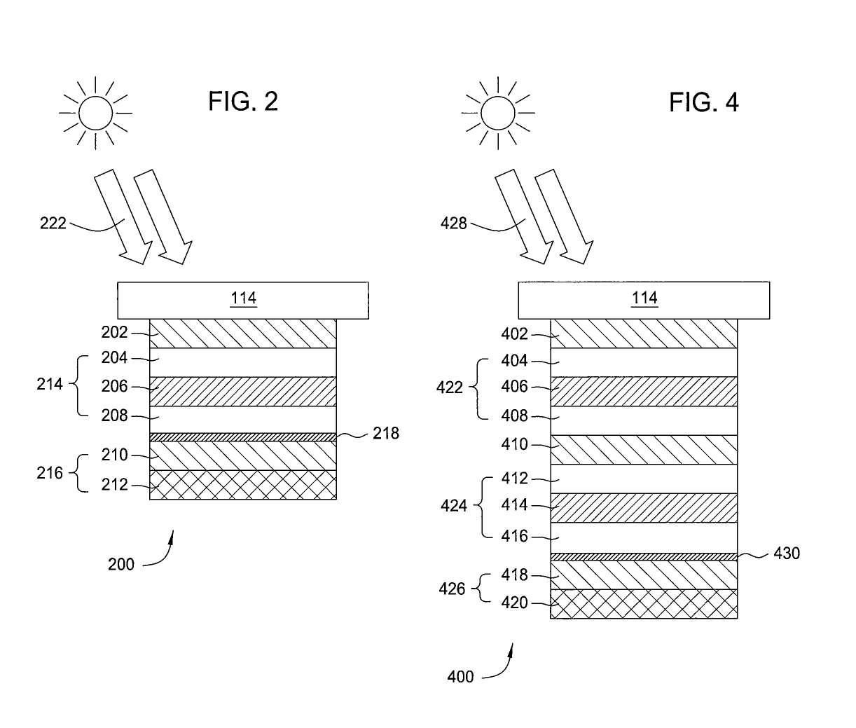

FIG. 2 depicts an exemplary cross sectional view of a thin film PV solar cell 200 in accordance with one embodiment of the present invention. In one embodiment, the thin film PV solar cell 200 is an amorphous silicon-based solar cell device that is formed on a substrate, such as the substrate 114 that is processed in the process chamber 100 of FIG. 1. The substrate 114 may be a thin sheet of metal, plastic, organic material, silicon, glass, quartz, or polymer, or other suitable material. The substrate 114 may have a surface area greater than about 1 square meter, such as greater than about 2 square meters. Alternatively, the thin film PV solar cell 200 may also be fabricated as crystalline, microcrystalline or other type of silicon-based thin films as needed.

A photoelectric unit 214 is formed on a transparent conductive layer, such as a TCO layer 202, disposed on the substrate 114. The photoelectric unit 214, which may be a photoelectric conversion unit or a photoelectric layer, includes a p-type semiconductor layer 204, an n-type semiconductor layer 208, and an intrinsic type (i-type) semiconductor layer 206 sandwiched therebetween as a photoelectric conversion layer. An optional dielectric layer (not shown) may be disposed between the substrate 114 and the TCO layer 202, between the TCO layer 202 and the p-type semiconductor layer, or between the intrinsic type (i-type) semiconductor layer 206 and the n-type semiconductor layer 208 as needed. In one embodiment, the optional dielectric layer may be a silicon layer including amorphous or polysilicon, SiON, SiN, SiC, SiOC, silicon oxide (SiO₂) layer, doped silicon layer, or any suitable silicon containing layer.

The p-type and n-type semiconductor layers 204, 208 may be silicon based materials doped by an element selected either from group III or V. A group III element doped silicon film is referred to as a p-type silicon film, while a group V element doped silicon film is referred to as a n-type silicon film. In one embodiment, the n-type semiconductor layer 208 may be a phosphorus doped silicon film and the p-type semiconductor layer 204 may be a boron doped silicon film. The doped silicon films 204, 208 include an amorphous silicon film (a-Si), a polycrystalline silicon film (poly-Si), and a microcrystalline silicon film (μc-Si) with a total thickness between about 5 nm and about 50 nm. Alternatively, the doped element in semiconductor layers 204, 208 may be selected to meet device requirements of the PV solar cell 200. The n-type and p-type semiconductor layers 204, 208 may be deposited by a CVD process or other suitable deposition process.

The i-type semiconductor layer 206 is a non-doped type silicon based film. The i-type semiconductor layer 206 may be deposited under process condition controlled to provide film properties having improved photoelectric conversion efficiency. In one embodiment, the i-type semiconductor layer 206 may be fabricated from i-type polycrystalline silicon (poly-Si), i-type microcrystalline silicon film (μc-Si), amorphous silicon (a-Si), or hydrogenated amorphous silicon (a-Si).

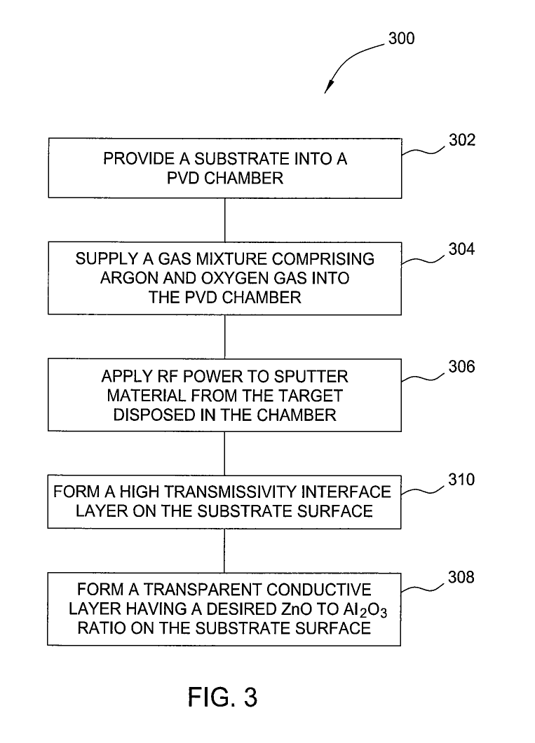

After the photoelectric unit 214 is formed on the TCO layer 202, a back reflector 216 is formed on the photoelectric unit 214. In one embodiment, the back reflector 216 may be formed by a stacked film that includes a transparent conductive layer, such as a TCO layer 210, and a conductive layer 212. The conductive layer 212 may be at least one of Ti, Cr, Al, Ag, Au, Cu, Pt, or their alloys. The TCO layer 210 may be fabricated from a material similar to the TCO layer 202 formed on the substrate 114. The TCO layers 202, 210 may be fabricated from a selected group consisting of tin oxide (SnO₂), indium tin oxide (ITO), zinc oxide (ZnO), or combinations thereof. In one exemplary embodiment, the TCO layers 202, 210 may be fabricated from a ZnO layer having a desired Al₂O₃ dopant concentration formed in the ZnO layer. Embodiments of a process 300 for forming a ZnO/Al₂O₃ layer are described below with reference to FIG. 3.

In one embodiment of the thin film PV solar cell 200, a transition layer 218 is formed between the photoelectric unit 214 and the back reflector 216. The transition layer 218 may be a thin layer having high transmittance that provides a reflective interface between the photoelectric unit 214 and the TCO layer 210.

Not wishing to be bound by theory, it is believed that the transition layer 218, if formed as a high transmittance layer, may provide a transition in refractive index between the photoelectric unit 214 and the TCO layer 210 that enhances reflectivity at the various interfaces. In some instances, the transition layer 218 may form a Bragg reflector that reflects some light back into the photoelectric unit 214 before it passes through the TCO layer 210. It should be noted that some of the light transmitted through the TCO layer 210 and reflected from the back reflector 216 will be lost by absorption during its passage through the TCO layer 210. Reflecting that light back into the photoelectric unit 214 before it passes through the TCO layer 210 reduces absorbance by the TCO layer 210. Using a high transmittance transition layer 218 reduces the opportunity for absorption of light by the transition layer 218.

Additionally, it is thought that a high transmittance transition layer 218 provides a smoother atomic level interfacial transition between the photoelectric unit 214 and the TCO layer 210, reducing recombination at the interface. While in some configurations a high transmittance transition layer 218 may tend to be electrically insulating, it generally has a thickness less than about 200 Å, for example between about 50 Å and about 200 Å, or between about 75 Å and about 150 Å, for example about 100 Å, and it is thought this thin layer provides a lower energy barrier to electron flow by smoothing the transition in crystal structure than the otherwise abrupt interface between the photoelectric unit 214 and the TCO layer 210. In other embodiments, the transition layer 218 may have a thickness between about 10 Å and about 1,500 Å, and may comprise a plurality of layers to form a Bragg reflector. In one embodiment, the plurality of layers may comprise materials with different refractive indices to provide a reflective layer that also transitions refractive index from the photoelectric unit 214 to the TCO layer 210. In one embodiment, the transition layer 218 may comprise a metal oxide layer having excess oxygen.

In one embodiment, the transition layer 218 comprises silicon from the photoelectric unit 214, as well as oxygen and metals. The transition layer 218 may have a composition that changes through the layer in some embodiments. Near the photoelectric unit 214, the composition of the transition layer 218 may resemble the composition of the photoelectric unit 214, and near the TCO layer 210, the composition of the transition layer 218 may resemble the composition of the TCO layer 210. In one embodiment, the transition layer 218 has a first composition that is silicon-rich and a second composition that is silicon-deficient. In another embodiment, the transition layer 218 may have a graded composition that varies smoothly through the layer, with silicon composition changing continuously from a high level to a low level, and metal composition changing continuously from a low level to a high level. In one embodiment, the transition layer 218 comprises silicon, oxygen, and metal atoms in a composition that varies between a silicon-rich composition, a nearly stoichiometric composition of silicon dioxide, a composition combining silicon with metal atoms and oxygen in an alloy, and a nearly stoichiometric composition of metal oxide. This variation may proceed smoothly, as in a graded composition, or in discrete steps or layers, for example, as a bilayer having a silicon-rich layer and a metal-rich layer. In another embodiment, the transition layer 218 may have a similarly graded composition comprising nitrogen instead of, or in addition to, oxygen.

The metal atoms in the transition layer 218 will generally be the metals used in the TCO layer 210. In some embodiments, the metals may include elements from the group consisting of aluminum, zinc, gallium, indium, and titanium. For example, if the TCO layer 210 is a zinc oxide layer doped with aluminum oxide to form a TCO composition, the transition layer 218 may comprise between about 0.5% and about 5% by weight of the TCO composition. In other embodiments, the TCO composition may be zinc oxide, zinc oxide doped with gallium oxide, zinc oxide doped with indium oxide, zinc oxide doped with titanium oxide, or zinc oxide doped with any mixture of aluminum oxide, gallium oxide, indium oxide, and titanium oxide.

In one embodiment, the transition layer 218 is a first TCO layer comprising excess oxygen or nitrogen or both. In such an embodiment, the TCO layer 210 is a second TCO layer having no nitrogen, and having the oxygen levels described above for a TCO layer. In such an embodiment, the excess oxygen or nitrogen incorporated in the first TCO layer lowers the refractive index of the first TCO layer to a level that provides high transmittance, for example a refractive index less than about 2.0. The first TCO layer may be between about 10 Angstroms thick to about 1,500 Angstroms thick. The first TCO layer may be entirely dopant-rich or may have a graded or stepped composition, with a region near the photoelectric unit 214 rich in oxygen, nitrogen, or both, and a region having a composition similar to the second TCO layer.

In embodiments depicted in FIG. 2, each of the TCO layers 202, 210 and the transition layer 218 may be deposited by a sputtering process, which may be a reactive sputtering process. The sputter deposition processes may be performed in the processing chamber 100, as described in FIG. 1.

FIG. 3 depicts a flow diagram of one embodiment of a sputtering deposition process 300 for depositing a transparent conductive layer, such as TCO layers 202, 210, on the substrate 114 or on the photoelectric unit 214. The process 300 may be stored in the memory 158 as instructions that when executed by the controller 148, cause the process 300 to be performed in the process chamber 100. In the embodiment depicted in FIG. 3, the process 300 may be performed in a thin film solar PVD system from Applied Materials, Inc., of Santa Clara, Calif. It is contemplated that the process 300 may be performed in other systems, including those from other manufacturers.

A substrate is disposed in a PVD chamber at 302. In one embodiment, the transparent conductive layer is a TCO layer that may be deposited as the TCO layer 202 on the substrate 114. In another embodiment, the TCO layer may be deposited as the TCO layer on the photoelectric unit 214 as the back reflector 216. The substrate may be subjected to a preclean process to remove any unwanted material from the substrate surface, which may be a photoelectric unit or other semiconductor or silicon surface. The preclean process may be performed by any convenient method, such as by sputtering with argon or helium plasma, or by plasma cleaning such as with a reactive plasma or etchant plasma. In one embodiment, a preclean gas mixture comprising argon, and possibly helium or hydrogen, is provided to the PVD chamber at a flow rate between about 500 sccm and about 5,000 sccm, such as between about 1,000 sccm and about 2,000 sccm. The gas mixture is ionized by applying RF, DC, or pulsed DC power between about 500 W and about 5 kW, such as between about 2 kW and about 4 kW. The ions are accelerated toward the substrate by applying an electrical bias, which may be an RF bias, a DC bias, or a pulsed DC bias, between about 100 V and about 1,000 V. The ions collide with the substrate to remove the unwanted material, which may be a native material or an oxide in some embodiments.

At 304, a process gas mixture is supplied into the sputter process chamber. The process gas mixture supplied in the sputter process chamber assists in bombarding the source material from the target 120 and may react with the sputtered material to form the desired TCO layer on the substrate surface. In one embodiment, the gas mixture may include a reactive gas and a non-reactive gas. Examples of non-reactive gases include, but are not limited to, inert gas, such as Ar, He, Xe, and Kr, or other suitable gases. Examples of reactive gas include, but are not limited to, O₂, N₂, N₂O, NO₂, H₂, NH₃, H₂O, among others.

In one embodiment, the argon (Ar) gas supplied into the sputter process chamber assists in bombarding the target to sputter materials from the target surface. In one embodiment, the target is a TCO material, and the argon gas sputters the target material onto the substrate. In another embodiment, the target is a metal or a metal-rich oxide, and the sputtered materials from the target react with the reactive gas in the sputter process chamber, thereby forming a TCO layer having desired film properties on the substrate. The TCO layer formed at different locations of the photoelectric conversion unit may require different film properties to achieve different current conversion efficiency requirement. For example, the bottom TCO layer 202 may require film properties, such as relatively high textured surface, high transparency, and high conductivity. The upper TCO layer 210 may require high transparency as well, however, the requirement for surface texturing is much less than that of the bottom TCO layer 202. The gas mixture and/or other process parameters may be varied during the sputtering deposition process, thereby creating the TCO layer with desired film properties for different film quality requirements.

The process gas mixture supplied into the sputter process chamber may include at least one of Ar, O₂ or H₂. O₂ gas may be supplied at a flow rate between about 0 sccm and about 100 sccm, such as between about 5 sccm and about 30 sccm, for example between about 5 sccm and about 15 sccm. Ar gas may be supplied into the processing chamber 100 at a flow rate between about 150 sccm and between 500 sccm. H₂ gas may be supplied into the processing chamber 100 at a flow rate between about 0 sccm and between 100 sccm, such as between about 5 sccm and about 30 sccm. Alternately, O₂ gas flow may be controlled at a flow rate per total flow rate between about 1 percent and about 10 percent to the total gas flow rate. H₂ gas flow may be controlled at a flow rate per total flow rate between about 1 percent and about 10 percent to the total gas flow rate.

In embodiments wherein the gas mixture supplied into the process chamber includes Ar and O₂ gas, the Ar gas flow rate supplied in the gas mixture is controlled at between about 90 percent by volume to 100 percent by volume and the oxygen gas flow rate is controlled about less than 10 percent by volume. In embodiments wherein the gas mixture supplied into the process chamber include Ar, O₂ and H₂ gas, the Ar gas flow rate supplied in the gas mixture is controlled at between about 80 percent by volume to 100 percent by volume, the oxygen gas flow rate is controlled about less than 10 percent by volume, and the hydrogen gas flow rate is also controlled at about less than 10 percent by volume.

As different gas mixtures supplied into the process chamber may provide different ion species that may react with the sputtered source material, the film properties of the TCO layer may be controlled by adjusting the composition of the gas mixture. For example, a greater amount of oxygen gas supplied in the gas mixture may result in a TCO layer having a higher quantity of oxygen elements formed in the resultant TCO layer. Accordingly, by controlling the amount of reactive gas along with different selection of targets used during sputtering, a TCO layer having tailored film properties may be obtained.

At 306, RF power is supplied to the target 120 to sputter the source material from the target 120 which reacts with the gas mixture supplied at operation 304. If the target 120 is a target comprising an alloy of zinc and aluminum, as a high voltage power is supplied to the zinc (Zn) and aluminum (Al) alloy target, the metal zinc and aluminum source material is sputtered from the target 120 in the form of zinc and aluminum ions, such as Zn⁺, Zn²⁺ and/or Al³⁺. The bias power applied between the target 120 and the substrate support 138 maintains a plasma formed from the gas mixture in the process chamber 100. The ions created by the gas mixture in the plasma bombard and sputter off material from the target 120. The reactive gases react with the growing sputtered film to form a layer with desired composition on the substrate 114. In one embodiment, a metal alloy target made of Zinc (Zn) and aluminum (Al) metal alloy is utilized as a source material of the target 120 for sputter process. In a target comprising Zn and Al, the ratio of Al metal included in the Zn target is controlled at about less than 3 percent by weight, such as less than 2 percent by weight, such as about less than 0.5 percent by weight, for example, about 0.25 percent by weight. In another embodiment, a metal alloy target made of zinc oxide (ZnO) and aluminum oxide (Al₂O₃) metal alloy is utilized as a source material of the target 120 for sputter process. The ratio of Al₂O₃ included in the ZnO target is controlled at between about less than 3 percent by weight, for example about less than 2 percent by weight, such as about less than 0.5 percent by weight, for example, about 0.25 percent by weight.

In the embodiment wherein the target is made of Zinc (Zn) and aluminum (Al) metals, the gas mixture supplied for sputtering may include argon and oxygen gas. The argon gas is used to bombard and sputter the target, and the oxygen ions dissociated from the O₂ gas mixture reacts with the zinc and aluminum ions sputtered from the target, forming a zinc oxide (ZnO) and aluminum oxide (Al₂O₃) containing TCO layer 202 or 210 on the substrate 114. The RF power is applied to the target 120 during processing. In the embodiment wherein the target 120 is fabricated from ZnO having Al₂O₃ doped therein, the gas mixture used to bombard the target may include argon but may or may not include O₂ gas. In this embodiment, the oxygen gas may be optionally eliminated as the target 120 provides the oxygen elements that are deposited in the TCO layer. In some embodiments, the hydrogen gas may be used in the gas mixture to assist in the bombardment and/or reaction with the source material from the target 120, regardless of the materials found in the target.

In one embodiment, a RF power of between about 100 Watts and about 60,000 Watts may be supplied to the target. Alternatively, the RF power may be controlled by RF power density supplied between about 0.15 Watts per centimeter square and about 15 Watts per centimeter square, for example, between about 4 Watts per centimeter square and about 8 Watts per centimeter square. Alternatively, the DC power may be supplied between about 0.15 Watts per centimeter square and about 15 Watts per centimeter square.

Several process parameters may be regulated in operations 304 and 306. In one embodiment, a pressure of the gas mixture in the process chamber 100 is regulated between about 2 mTorr and about 10 mTorr. The substrate temperature may be maintained between about 25 degrees Celsius and about 100 degrees Celsius. The processing time may be processed at a predetermined processing period or after a desired thickness of the layer is deposited on the substrate. In one embodiment, the process time may be processed at between about 30 seconds and about 400 seconds. In one embodiment, the thickness of the TCO layer is between about 5,000 Å and about 10,000 Å. In the embodiment wherein a substrate with different dimension is desired to be processed, process temperature, pressure and spacing configured in a process chamber with different dimension do not change in accordance with a change in substrate and/or chamber size.

At 308, as the ions dissociated from the gas mixture react with sputtered off material from the target 120, a TCO layer with desired composition is therefore formed on the substrate surface. In one embodiment, the TCO layer as deposited is a ZnO layer having a desired amount of aluminum oxide dopant formed therein. It is believed that the TCO layer having a desired amount of Al₂O₃ dopant formed in the ZnO layer can efficiently improve current conversion efficiency of the photoelectric conversion unit. The aluminum elements formed in the TCO layer may provide higher film conductivity, thereby assisting carrying greater amount of current in the TCO layer. Additionally, it is believed that higher amount of oxygen elements formed in the TCO layer increases film transmittance that allows greater amount of current generated in the photoelectric conversion unit. Furthermore, a high film transparency is desired to maximize the light transmitting efficiency. Accordingly, by controlling a desired amount of aluminum oxide formed in the zinc containing layer, the TCO layer having desired film properties, such as high transmittance and high current conversion efficiency, may be obtained.

In one embodiment, an oxygen rich portion of the TCO layer may be provided by adjusting the gas mixture supplied into the process chamber during sputter process. The oxygen rich portion generally has oxygen above a stoichiometric amount. For example, an oxygen rich ZnO layer has more than about 50 atomic percent oxygen, such as more than about 52 atomic percent or more than about 55 atomic percent oxygen. Alternatively, the oxygen source may be provided from a selected target having metal oxide alloy prefabricated in the target so that when sputtering, both metallic and oxygen elements may be sputtered off the target and deposited on the substrate surface. In the embodiment wherein the selected target 120 is fabricated from a zinc and aluminum metal alloy, a gas mixture including argon and oxygen may be used to provide oxygen ions, when dissociated, to react with the zinc and aluminum ions sputtered from the target, forming zinc oxide layer having desired concentration of aluminum oxide on the substrate. In the embodiment wherein the selected target 120 is fabricated from zinc oxide and aluminum oxide, a gas mixture including argon gas may be used. The oxygen gas may be optionally supplied in the gas mixture. The hydrogen gas may be optionally supplied in both cases.

As discussed above, a TCO layer having a desired amount of Al₂O₃ dopant formed in the ZnO layer may improve the film conductivity and film transparency. The Al₂O₃ dopant source may be provided from the target during processing. In one embodiment, the ratio of Al₂O₃ included in the ZnO target is controlled at between about less than 3 percent, for example about less than 2 percent by weight, such as about less than 0.5 percent by weight, for example, about 0.25 percent by weight. In one embodiment, the lower the dopant concentration of Al₂O₃ formed in the ZnO target, a relatively higher amount of oxygen gas may be supplied in the gas mixture during sputtering to maintain a desired transmittance formed in the TCO layer. For example, if the ratio of Al₂O₃ doped in the ZnO target is about 0.5 percent by weight, the gas mixture may have an oxygen gas flow rate about 5 percent by volume and argon gas flow rate about 95 percent by volume. However, if the ratio of Al₂O₃ doped in the ZnO target is as low as about 0.25 percent by weight, the gas mixture may have a higher oxygen gas flow rate about 7-8 percent by volume and lower argon gas flow rate about 92-93 percent by volume. Since both oxygen elements and Al₂O₃ elements formed in the TCO layer are believed to reduce light absorption in the film, when a lower dopant concentration of Al₂O₃ target is used, a higher oxygen gas in the gas mixture may be used to compensate the lower dopant concentration of Al₂O₃ formed in the target. In some embodiments, hydrogen gas may also be utilized to increase the resultant film transmittance.

In one embodiment, the TCO layer has an Al₂O₃ dopant concentration between about 0.25 percent and about 3 percent in a ZnO based layer. In another embodiment, the TCO layer may be a ZnO layer, or instead of an Al₂O₃ dopant may have similar levels of gallium oxide, indium oxide, or titanium oxide. The stoichiometric amount of oxygen in an aluminum doped ZnO layer ranges from about 54 atomic percent for an Al₂O₃ concentration of 0.25 percent by weight to about 66 atomic percent for an Al₂O₃ concentration of 3 percent by weight. An aluminum doped ZnO layer having excess oxygen will thus have atomic percent oxygen greater than these amounts, for example greater than 54 atomic percent oxygen for a dopant concentration of about 0.25 percent by weight or greater than about 66 atomic percent oxygen for a dopant concentration of about 3 percent by weight. Thus, a doped TCO layer having excess oxygen may have greater than about 55 atomic percent oxygen, greater than about 60 atomic percent oxygen, greater than about 65 atomic percent oxygen, or greater than about 70 atomic percent oxygen, depending on the type and quantity of dopant in the TCO layer.

At 310, a high transmittance transition layer is formed on the surface of the substrate. In one embodiment, the operation of 310 is performed only when using the process 300 to form a transmitting conductive layer for a back reflector such as the transmitting conductive layer 210 of FIG. 2. The interface layer is formed between the photoelectric unit and the back reflector TCO layer to smooth the interfacial transition between the two layers. In one embodiment, the interface layer is formed by a reactive sputtering process adapted to add an absorption reducing dopant to the surface of the substrate. In one embodiment, the absorption reducing dopant is oxygen. In another embodiment, the transparency promoting dopant is excess oxygen.

The sputtering conditions for the operation 306 may be adjusted to achieve a low sputtering rate so that excess oxygen is deposited on the silicon surface of the photoelectric unit. In one embodiment, the sputtering power transmitted to the target may be reduced to between about 0.5% and about 10% of the power used to form the transparent conductive layer in operation 308, such as between about 1% and about 5%, or about 1.5%. Thus, an initial sputtering power between about 250 W and about 5 kW, such as between about 500 W and about 2.5 kW, or between about 1 kW and about 1.5 kW, may be used to form the interface layer. The low sputtering power produces metals from the target into the reaction atmosphere at a low rate, increasing the partial pressure of oxygen near the substrate surface. Excess oxygen is deposited at the surface, penetrating the silicon and forming a silicon and oxygen matrix incorporating low levels of metals from the target.

After depositing a transition layer to a thickness of less than about 200 Å, such as between about 50 Å and about 200 Å, or between about 75 Å and about 150 Å, for example about 100 Å, sputtering conditions may be adjusted to deposit the TCO layer as described above. The conditions may be adjusted gradually, ramping the power up to the level desired over time to transition the composition of the interface layer to the TCO layer smoothly. Such ramping may produce an interface layer with a graded composition that smoothly transitions from a first composition resembling the composition of the photoelectric unit to a second composition resembling the composition of the TCO layer, as described above in connection with FIG. 3. In another embodiment, the power level may be adjusted in discrete steps to deposit multiple sublayers having discrete compositions. In one embodiment, the power level may be adjusted from a first power level adapted to produce a reaction mixture comprising excess oxygen to a second power level adapted to deposit the TCO layer through a third power level between the first and second power levels. Such an operation will deposit a bilayer having a first composition that is silicon-rich and a second composition that is metal-rich.

In another embodiment, excess oxygen may be added to the gas mixture supplied in operation 304 to form the interface layer at 310. The excess oxygen will have the same effect in raising the partial pressure of oxygen at the surface of the substrate, as the lower power setting described above. In one embodiment, the oxygen-containing gas may be supplied to the PVD chamber for a time period prior to applying the RF power in operation 306 to achieve deposition of the oxygen-containing interface layer. In reference to the gas mixture described above, oxygen may be added to the gas mixture at a flow rate that is at least about 25% by volume of the total flow rate of the gas mixture, or at least about 50% by volume of the gas mixture. In another embodiment, oxygen may be added to the gas mixture at a flow rate that is between about 0.5% and about 15% by volume of the total flow rate of the gas mixture. In one embodiment, a gas mixture for forming a high transparency interface layer may comprise between about 150 sccm and about 500 sccm argon and between about 50 sccm and about 500 sccm of oxygen gas. In one embodiment, the gas mixture may further comprise between about 5 sccm and about 30 sccm of hydrogen gas. In an exemplary embodiment, a gas mixture for forming a high transparency transition layer comprises about 200 sccm of oxygen gas, about 200 sccm of argon gas, and about 20 sccm of hydrogen gas.

The oxygen composition of the sputtering gas may be adjusted from an excess level to the target level for depositing the transmitting conductive layer by ramping or by discrete steps, with effects similar to those described above. As the oxygen flow rate in the gas mixture is reduced, the flow rate of other components may be increased to keep the total gas flow rate constant. For example, in the exemplary embodiment above, the oxygen flow rate may be ramped from about 200 sccm to about 20 sccm while the argon flow rate is ramped from about 200 sccm to about 380 sccm.

In one aspect of the present invention the transition layer is at least partially formed by consuming a portion of the layer over which the interface layer is deposited. In one example, the transition layer 218 is partially formed by consuming a portion of the silicon containing layer in the photoelectric unit 214 to form a region of the transition layer 218 that may comprises silicon dioxide, or silicon dioxide and TCO elements. It is believed that the growth of the transition layer from a portion of the photoelectric unit 214 will tend to form a smooth structural interface, transitioning the crystal structure of the material in a way that minimizes conductive barriers, and the high transparency of the transition layer will avoid light absorption and electron recombination at the interface.

In operation, the incident light 222 provided by the environment is supplied to the PV solar cell 200. The photoelectric unit 214 in the PV solar cell 200 absorbs the light energy and converts the light energy into electrical energy by operation of the p-i-n junctions formed in the photoelectric unit 214, thereby generating electricity or energy. Alternatively, the PV solar cell 200 may be fabricated or deposited in a reversed order. For example, the substrate 114 may be disposed over the back reflector 216.

FIG. 4 depicts an exemplary cross sectional view of a tandem type PV solar cell 400 fabricated in accordance with another embodiment of the present invention. Tandem type PV solar cell 400 has a similar structure of the PV solar cell 200 including a bottom TCO layer 402 formed on the substrate 114, which faces incident light 428, and a first photoelectric unit 422 formed on the TCO layer 402. The first photoelectric unit 422, which may be a photoelectric conversion unit or a photoelectric layer, may be μc-Si based, poly-silicon or amorphous based photoelectric conversion unit as described with reference to the photoelectric unit 214 of FIG. 2. An intermediate layer 410 may be formed between the first photoelectric unit 422 and a second photoelectric unit 424. The intermediate layer 410 may be a TCO layer sputter deposited by the process 300 described above. Alternatively, the intermediate layer 410 may be a SiO, SiC, SiON, SiOCN or other suitable doped silicon alloy layer. The combination of the first photoelectric unit 422 and the second photoelectric unit 424 as depicted in FIG. 4 increases the overall photoelectric conversion efficiency.

The first photoelectric unit 422 may be μc-Si based, polysilicon or amorphous based, and has a first p-type semiconductor layer 404, a first i-type semiconductor layer 406, and a first n-type semiconductor layer 408. The first i-type semiconductor layer 406 may be a μc-Si or α-Si film, and may be sandwiched between the first p-type semiconductor layer 404 and the first n-type semiconductor layer 408.

The second photoelectric unit 424 may be μc-Si based, polysilicon or amorphous based, and have a second i-type semiconductor layer 414, which may be a μc-Si or α-Si, sandwiched between a second p-type semiconductor layer 412 and a second n-type semiconductor layer 416. A back reflector 426 is disposed on the second photoelectric unit 424. The back reflector 426 may be similar to back reflector 216 as described with reference to FIG. 2. The back reflector 426 may comprise a conductive layer 420 formed on a top TCO layer 418. The materials of the conductive layer 420 and the top TCO layer 418 may be similar to the conductive layer 212 and TCO layer 210 as described with reference to FIG. 2.

The tandem type PV solar cell 400 further comprises a high transmittance transition layer 430 similar to the high transmittance transition layer 218 of FIG. 2, and formed using one of the embodiments of FIG. 3. A high transmittance transition layer may also be used with the intermediate layer 410, if desired, to reduce the effects of abrupt transitions in crystal structure. If the intermediate layer 410 has a composition that results in a different crystal structure from the adjacent layers, for example if the intermediate layer 410 is a TCO layer and the adjacent layers are silicon-containing layers, a high transmissivity interface layer may improve device efficiency.

The embodiments of FIGS. 2 and 4 may also benefit from a high transmittance transition layer disposed between the TCO layer 202 and the photoelectric unit 214 in the embodiment of FIG. 2 and between the TCO layer 402 and the first photoelectric unit 422 in the embodiment of FIG. 4. In either case, the transition layer is formed after formation of the TCO layer is complete, and may be formed by adding oxygen to the reaction that deposits the semiconductor layers 204 and 404, respectively. For example, if a silane reaction mixture is activated with a plasma to deposit silicon on a TCO layer such as the TCO layers 202 and 402, respectively, oxygen may be added to the reaction mixture in approximately stoichiometric quantities to deposit a thin layer having high transmittance.

In other embodiments, nitrogen may be used instead of, or in addition to, oxygen to form a transition layer. In embodiments, featuring nitrogen as a dopant, aluminum is generally not used in portions of the TCO layer likely to contain nitrogen because aluminum nitride has relatively high absorption of light. Thus, in embodiments wherein nitrogen is added to the silicon surface, the metal oxide component will generally be free of aluminum. Adding nitrogen to the silicon surface may form a thin layer of silicon nitride, or a thin layer of silicon and nitrogen containing material, with low refractive index. As described above, the difference in refractive index between the transition layer and the silicon and TCO layers creates a reflective interface that captures light that would otherwise be absorbed by the TCO layer. The low refractive index of the transition layer prevents absorption of light by the transition layer.

Any mixture of oxygen and nitrogen may be used to form a transition layer. For example, in one embodiment, a zinc oxide target is sputtered onto the silicon surface of a solar cell such as those illustrated in FIGS. 2 and 4 by providing a process gas of argon, oxygen, and nitrogen, wherein the oxygen and nitrogen together are no more than about 15% of the volume of the process gas. Processing conditions similar to other embodiments described herein may be used to deposit a ZnO layer having excess oxygen as well as nitrogen incorporated into the layer. Embodiments featuring excess oxygen as well as nitrogen may include providing a process gas having 15% or less nitrogen by volume along with 15% or more, 25% or more, or 50% or more oxygen by volume. At the interface with the silicon surface of the photoelectric unit, the oxygen and nitrogen penetrate the silicon surface to form a thin layer of silicon, oxygen, and nitrogen containing material having a refractive index lower than the silicon and TCO layers. The ZnO transition layer having excess oxygen and nitrogen will have refractive index between that of the silicon, oxygen, and nitrogen containing layer and the TCO layer. The layer of silicon, oxygen, and nitrogen containing material may be thin, such as less than about 50 Å, and may be only one or two atomic layers thick. The ZnO transition layer may be from about 10 Å to about 1,500 Å thick.

A TCO layer may be formed on the ZnO transition layers described above. In one embodiment, less excess oxygen and nitrogen may be added to form the second TCO layer, while in another embodiment, the second TCO layer may be formed by sputtering a ZnO target using only argon gas. The lower oxygen and/or nitrogen content of the second TCO layer produces higher refractive index than the ZnO transition layer above. Depositing layers with progressively higher refractive index leads to reflective interfaces that increase light capture behind the photoelectric unit. The TCO layer may be between about 0 Å and about 1,500 Å. It should be noted that the ZnO transition layer may be used alone as a TCO layer in some embodiments. In one embodiment the thickness of the ZnO transition layer and the TCO layer together may be between about 500 Å and about 1,500 Å.

The transition layers described herein generally have the formula Si_{w}OₓN_{y}M_{z}, wherein M is a metal, such as zinc, or a combination of metals in any convenient proportion, such as a zinc/aluminum mixture as described above. At the surface of the photoelectric unit, w is about 1.0, x is between about 0 and about 2.0, y is between about 0 and about 1.0, and z is less than about 0.1, for example near zero. The sum of x and y is greater than zero throughout the transition layer. Away from the surface of the photoelectric unit, w is less than about 0.1, for example near zero, z is about 1.0, y is near zero, and x is between about 0.7 and about 1.5, depending on the combination of metals used. As such, the transition layer may be a bilayer having a first layer with composition corresponding to the composition described above near the surface of the photoelectric unit, and a second layer with composition corresponding to the composition described above away from the surface of the photoelectric unit. The composition of the transition bilayer may vary as two substantially discrete layers, or may be graded.

Thus, methods for sputter depositing a transition layer between a photoelectric unit and back contact layer of a photovoltaic device are provided. The transition layer may be high transmittance, and generally has lower refractive index than the photoelectric unit layer and the back contact TCO layer. In some embodiments, a silicon containing layer having high transmittance is formed. The silicon containing layer may contain oxygen and/or nitrogen. In other embodiments, a metal oxide layer, which may be a TCO layer, is formed with excess oxygen and/or nitrogen. The method advantageously produces a transition layer that improves light capture at the back contact layer without adding absorption. In this manner, the transition and TCO layers efficiently increase the photoelectric conversion efficiency and device performance of the PV solar cell as compared to conventional methods.

While the foregoing is directed to embodiments of the invention, other and further embodiments of the invention may be devised without departing from the basic scope thereof.

What is claimed is:

1. A method of forming a solar cell, comprising:
forming a photoelectric unit on a substrate;
forming a back contact layer on the substrate; and
forming a transition layer between the photoelectric unit and the back contact layer, the transition layer having a refractive index lower than either the photoelectric unit or the back contact layer.

2. The method of claim 1, wherein the transition layer comprises silicon and at least one of oxygen and nitrogen.

3. The method of claim 1, wherein forming the transition layer between the photoelectric unit and the back contact layer comprises forming a metal oxide layer having excess oxygen on the photoelectric unit.

4. The method of claim 1, wherein forming the transition layer comprises forming an alloy layer comprising silicon, a metal, and at least one of oxygen and nitrogen.

5. The method of claim 4, wherein the metal comprises an element selected from the group consisting of zinc, aluminum, gallium, titanium, and combinations thereof.

6. The method of claim 1, wherein forming the transition layer comprises adding oxygen, nitrogen, or both to the surface of the photoelectric unit and consuming a portion of the photoelectric unit.

7. The method of claim 6, wherein forming the transition layer comprises forming a transmitting conducting layer using a first deposition reaction and a second deposition reaction, wherein the first deposition reaction is performed at conditions selected to add oxygen or nitrogen or both to the surface of the photoelectric unit, and the second deposition reaction is performed at conditions selected to form a metal oxide layer having nitrogen or excess oxygen or both.

8. The method of claim 3, wherein the metal oxide layer having excess oxygen comprises at least about 55 atomic percent oxygen.

9. A method of forming a transparent conductive layer, comprising:
supplying a gas mixture comprising at least one of nitrogen and excess oxygen to a processing chamber;
sputtering a source material from a target comprising zinc in the processing chamber; and
reacting the source material with the gas mixture to deposit a transparent conductive layer comprising at least one of nitrogen and excess oxygen.

10. The method of claim 9, wherein the gas mixture further comprises hydrogen.

11. The method of claim 9, wherein the gas mixture is nitrogen-free, and further comprising reducing the oxygen in the gas mixture to sputter deposit a transparent conductive layer having substantially stoichiometric oxygen.

12. The method of claim 9, wherein the gas mixture comprises nitrogen, and further comprising stopping the nitrogen and supplying oxygen to the gas mixture to sputter deposit a transparent conductive layer having substantially stoichiometric oxygen.

13. The method of claim 9, wherein the target further comprises at least one element from the group of gallium and titanium.

14. The method of claim 9, wherein sputtering a source material from a target comprising zinc in the processing chamber comprises applying a first sputtering power to the target for a first period of time and then applying a second sputtering power to the target for a second period of time, wherein the second sputtering power is at least three times the first sputtering power.

15. The method of claim 14, further comprising continuously ramping from the first sputtering power to the second sputtering power.

16. The method of claim 1, wherein the photoelectric unit comprises a microcrystalline photoelectric layer and an amorphous photoelectric layer, and each of the photoelectric layers comprises a p-type layer, an n-type layer, and an intrinsic layer.

17. The method of claim 9, wherein the first composition comprises at least about 0.5% oxygen by volume.

18. A solar cell device, comprising:
a photoelectric unit;
a transmitting conducting layer adjacent to the photoelectric unit; and
a transition layer comprising silicon and at least one of oxygen and nitrogen between the photoelectric unit and the transmitting conducting layer.

19. The solar cell device of claim 18, wherein the transition layer has a thickness less than about 1,500 Å.

20. The solar cell device of claim 18, wherein the transition layer comprises at least about 55 atomic percent oxygen.

21. The solar cell device of claim 18, wherein the transition layer is a bilayer comprising a first and second layer, each of which has the general formula Si_{w}OₓN_{y}M_{z}, M is a metal or combination of metals, w is about 1.0 in the first layer and less than about 0.1 in the second layer, z is less than about 0.1 in the first layer and about 1.0 in the second layer, x is between about 0 and about 2.0 in the first layer and between about 0.7 and about 1.5 in the second layer, y is between about 0 and about 1.0 in the first layer and less than about 0.1 in the second layer, and x+y>0 in each layer.

22. The solar cell device of claim 18, wherein the photoelectric unit comprises a p-type semiconductor layer, an n-type semiconductor layer, and an intrinsic type semiconductor layer.

23. The solar cell device of claim 18, wherein the photoelectric unit comprises a microcrystalline photoelectric layer and an amorphous photoelectric layer, and each of the photoelectric layers comprises a p-type layer, an n-type layer, and an intrinsic layer.
